(19) United States
(12) Patent Application Publication
(10) Pub. No.: US 2014/0290581 A1
(43) Pub. Date: Oct. 2, 2014

(54) DEPOSITION APPARATUS

(71) Applicants: Seok Min Kang, Seoul (KR); Moo Seong Kim, Seoul (KR); Heung Teak Bae, Seoul (KR); Seo Yong Ha, Seoul (KR)

(72) Inventors: Seok Min Kang, Seoul (KR); Moo Seong Kim, Seoul (KR); Heung Teak Bae, Seoul (KR); Seo Yong Ha, Seoul (KR)

(73) Assignee: LG INNOTEK CO., LTD., Seoul (KR)

(21) Appl. No.: 14/128,883

(22) PCT Filed: Jun. 21, 2012
(86) PCT No.: PCT/KR2012/004917

§ 371 Date: Apr. 22, 2014

(30) Foreign Application Priority Data
Jun. 21, 2011 (KR) 10-2011-0060353

(51) Int. Cl. H01L 21/67

(52) U.S. Cl. CPC H01L 21/67017
USPC 118/730

(57) ABSTRACT

Disclosed is a deposition apparatus. The deposition apparatus comprises a susceptor into which reaction gas is introduced; a holder supporting a substrate in the susceptor; and a rotating driver for rotating the holder.

### TECHNICAL FIELD

The embodiment relates to a deposition apparatus.

### BACKGROUND ART

In general, among technologies to form various thin films on a substrate or a wafer, a CVD (Chemical Vapor Deposition) scheme has been extensively used. The CVD scheme results in a chemical reaction. According to the CVD scheme, a semiconductor thin film or an insulating layer is formed on a wafer surface by using the chemical reaction of a source material.

The CVD scheme and the CVD device have been spotlighted as an important thin film forming technology due to the fineness of the semiconductor device, power device and the development of high-power and high-efficiency LED. Recently, the CVD scheme has been used to deposit various thin films, such as a silicon layer, an oxide layer, a silicon nitride layer, a silicon oxynitride layer, or a tungsten layer, on a wafer.

### DISCLOSURE OF INVENTION

### Technical Problem

The embodiment provides a deposition apparatus capable of forming a thin film having a uniform thickness.

### Solution to Problem

According to the embodiment, the deposition apparatus comprises a susceptor into which reaction gas is introduced; a holder supporting a substrate in the susceptor; and a rotating driver for rotating the holder.

According to the embodiment, the deposition apparatus comprises a susceptor into which reaction gas is introduced; a first holder supporting a first substrate in the susceptor; a first rotating driver for rotating the first holder; a second holder supporting a second substrate on the first holder; and a second rotating driver for rotating the second holder.

### Advantageous Effects of Invention

As described above, the deposition apparatus according to the embodiment rotates the holder using the rotating driver. Accordingly, the disposition apparatus according to the embodiment may form a thin film on a wafer while rotating the wafer.

Therefore, the deposition apparatus according to the embodiment may uniformly form the thin film on the wafer. Particularly, the deposition apparatus according to the embodiment may uniformly form a silicon carbide epitaxial layer on a silicon carbide wafer.

### BRIEF DESCRIPTION OF DRAWINGS

FIG. 1 is a schematic view showing a silicon carbide epitaxial layer growth apparatus according to a first embodiment.

FIG. 2 is an exploded perspective view showing a deposition part.

FIG. 3 is an exploded perspective view showing a deposition part.

FIG. 4 is a perspective view showing a wafer support part.

FIG. 5 is a view showing a susceptor and the wafer support part.

FIG. 6 is a view showing a rotating driver.

FIG. 7 is an exploded perspective view showing a wafer support part according to a second embodiment.

FIG. 8 is a side view showing a wafer support part according to a second embodiment.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each layer shown in the drawings may be exaggerated, omitted or schematically drawn for the purpose of convenience or clarity. In addition, the size of elements does not utterly reflect an actual size.

Hereinafter, the embodiment will be described in detail with reference to accompanying drawings.

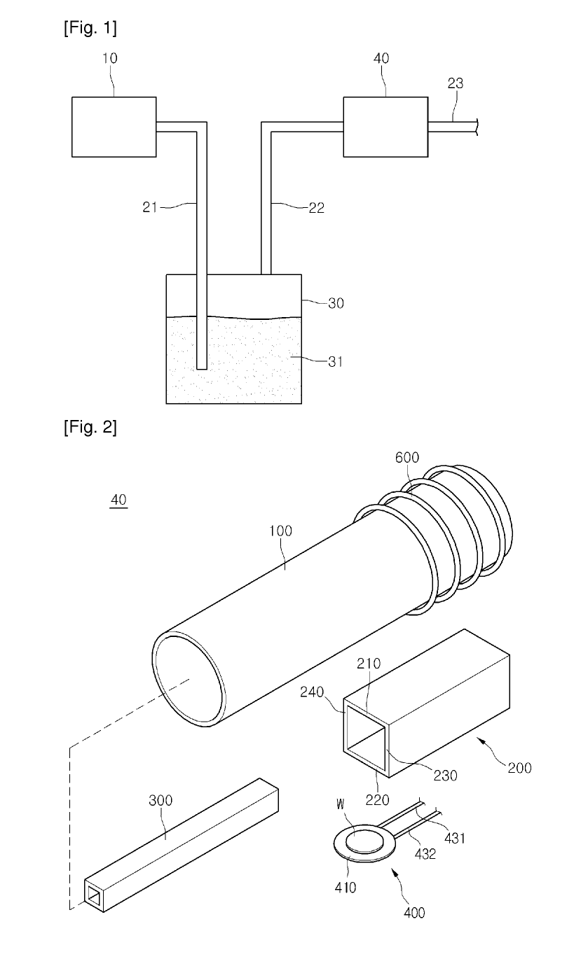

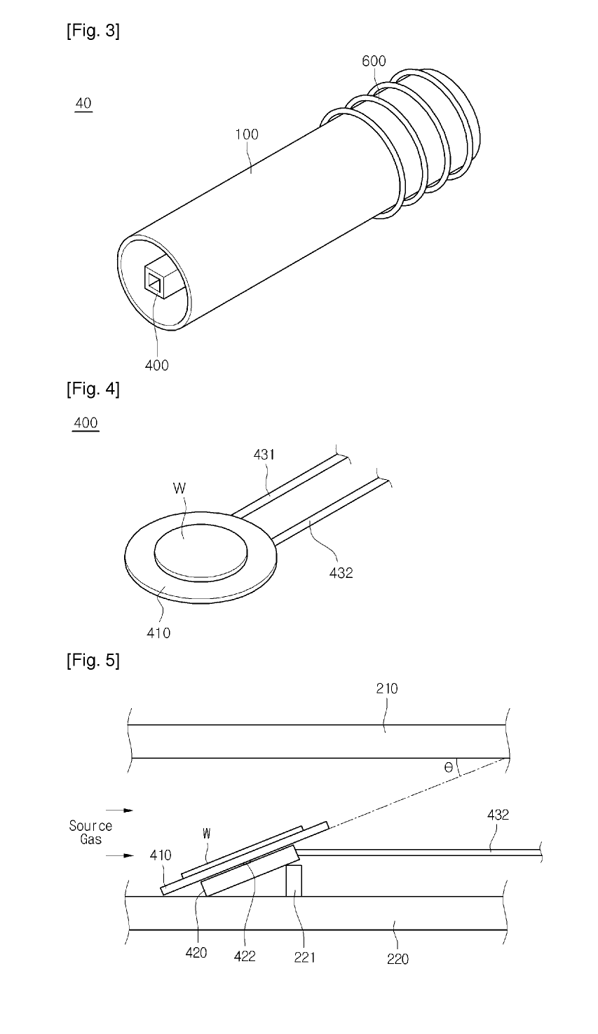

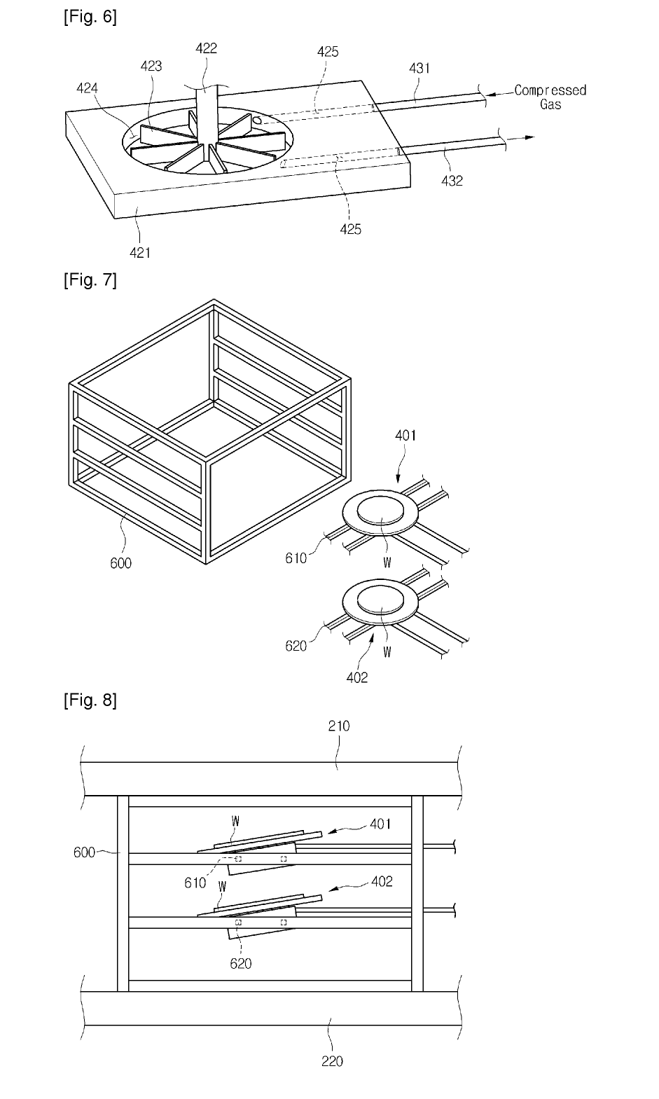

FIG. 1 is a schematic view showing a silicon carbide epitaxial layer growth apparatus according to a first embodiment. FIG. 2 is an exploded perspective view showing a deposition part. FIG. 3 is an exploded perspective view showing a deposition part. FIG. 4 is a perspective view showing a wafer support part. FIG. 5 is a view showing a susceptor and the wafer support part. FIG. 6 is a view showing a rotating driver.

Referring to FIGS. 1 to 6, the silicon carbide epitaxial layer growth apparatus according to the embodiment comprises a carrier gas supply part 10, a reaction gas supply part 30, and a deposition part 40.

The carrier gas supply part 10 supplies carrier gas to the reaction gas supply part 30. The carrier gas has very low reactivity. For instance, the carrier gas may comprise nitrogen or inert gas. In particular, the carrier gas supply part 10 may supply the carrier gas to the reaction gas supply part 30 through a first supply line 21.

The reaction gas supply part 30 generates the reaction gas. Further, the reaction gas supply part 30 receives liquid 31 for generating the reaction gas. For example, the liquid 31 may evaporate such that the reaction gas is generated.

An end portion of the first supply line 21 may be immersed in the liquid 31. Accordingly, the carrier gas is supplied in the liquid 31 through the first supply line 21. As a result, a bubble including the carrier gas may be produced in the liquid 31.

The liquid 31 and the reaction gas may comprise a compound having silicon and carbon. For example, the liquid 31 and the reaction gas may comprise methyltrichlorosilane (MTS).

The reaction gas supply part 300 may comprise a heating member for applying heat to the liquid 31. The heating member may apply the heat to the liquid to evaporate the liquid 31. An amount of evaporated reaction gas may be suitably controlled according to an amount of the heat applied by the heating member.

The reaction gas supply part 30 supplies the reaction gas to the deposition part 40 through the second supply line 22. That is, the reaction gas is supplied to the deposition part 40 by the reaction gas supply part 30, flow of the carrier gas, and the evaporation of the liquid 31.

The deposition part 40 is connected to the second supply line 22. The deposition part 40 receives the reaction gas from the reaction gas supply part 30 through the second supply line 22.

The deposition part 40 comprises a wafer W on which an epitaxial layer will be formed. The deposition part 40 forms the epitaxial layer using the reaction gas. That is, the deposition part 40 forms a thin film on the wafer W using the reaction gas.

Referring to FIGS. 2 to 7, the deposition part 40 comprises a chamber 100, a susceptor 200, a source gas line 300, a wafer support member 400, and an induction coil 600.

The chamber 100 may have the shape of a cylindrical tube. To the contrary, the chamber 100 may have the shape of a rectangular box. The chamber 100 may comprise the susceptor 200, the source gas line 300, and the wafer support member 400.

Although not shown, the chamber 100 may be additionally provided at one side thereof with a gas inlet allowing precursors to be introduced and a gas outlet allowing gas discharge.

Further, both end portions of the chamber 100 are closed, and the chamber 10 may prevent the introduction of external gas and maintain the degree of vacuum. The chamber 100 may comprise quartz representing high mechanical strength and superior chemical durability. Further, the chamber 100 represents an improved heat resistance property.

An adiabatic member may be further provided in the chamber 100. The adiabatic member may preserve heat in the chamber 100. A material used for the adiabatic member may comprise nitride ceramic, carbide ceramic, or graphite.

The susceptor 200 is provided in the chamber 100. The susceptor 200 comprises the wafer support member 400. Further, the susceptor 200 comprises a substrate such as the wafer W. In addition, the reaction gas is introduced into the susceptor 200 from the reaction gas supply part 10 through the second supply line 22 and the source gas line 300.

Referring to FIGS. 2 to 4, the susceptor 200 may comprise a susceptor upper plate 210, a susceptor lower plate 220, and susceptor lateral plates 230 and 240. In addition, the susceptor upper and lower plates 210 and 38 face each other.

The susceptor 200 may be manufactured by placing the susceptor upper and lower plates 210 and 220, placing the susceptor lateral plates 230 and 240 at both sides of the susceptor upper and lower plates 210 and 220, and bonding the susceptor upper and lower plates 210 and 220 with the susceptor lateral plates 230 and 240.

However, the embodiment is not limited thereto. For instance, a space for a gas passage can be made in the rectangular parallelepiped susceptor 200.

The wafer support part 400 may be further provided on the susceptor lower plate 220. Air flows through the space between the susceptor upper and lower plates 210 and 220, so that the deposition process can be performed. The susceptor lateral plates 230 and 240 prevent reaction gas from flowing out when the air flows in the susceptor 200.

The susceptor 200 comprises graphite representing a high heat resistance property and a superior workability, so that the susceptor 200 can endure under the high temperature condition. Further, the susceptor 200 may have a structure in which a graphite body is coated with silicon carbide. Meanwhile, the susceptor 200 itself may be induction-heated.

Reaction gas supplied from the susceptor 200 is decomposed into radical by heat, and then the radical may be deposited on the wafer W. For example, MTS is decomposed into radical including silicon or carbon, so that a silicon carbide epitaxial layer may be grown on the wafer W. In more detail, the radical may comprise CH₃, CH₄, SiCl₃, or SiCl₂.

The source gas line 300 is provided in the chamber 100. The source gas line 300 is connected to the susceptor 200. In more detail, the source gas line 300 supplies the reaction gas to the susceptor 200. Further, the source gas line 300 is directly or indirectly connected to the second supply line 22.

The source gas line 300 may have the shape of a rectangular tube. The source gas line 300 may comprise a material such as quartz.

The wafer support member 400 is provided in the susceptor 200. In more detail, the wafer support member 400 may be provided at a rear of the susceptor 200 when viewed in the flowing direction of the source gas. The wafer support part 400 supports the wafer W. Further, the wafer support member 400 rotates the wafer W.

Referring to FIGS. 4 to 6, the wafer support part 400 comprises a holder 410 and a rotating driver 420.

The holder 410 is provided under the wafer W. That is, the holder 410 supports the wafer W. The holder 410 rotates the wafer W. That is, the holder 410 rotates the wafer W through the rotation thereof. The holder 410 may has the shape of a plate.

The rotating driver 420 is provided under the holder 410. The rotating driver 420 rotates the holder 410. The rotating driver 420 transfers a rotating power to the holder 410. The rotating driver 420 comprises a housing 421, a shaft 422, a plurality of pins 423, a compressed gas supply line 431, and a compressed gas discharge line 432.

The housing 421 receives the shaft 422 and the pins 423. A receiving groove 423, a first passage 425, and a second flow passage 426 are provided in the housing 421. The housing 421 may comprise graphite or silicon carbon.

The shaft 422 may be rotatably fixed to the housing 421. The shaft 422 is connected to the holder 410. One end portion of the shaft 422 of the shaft 422 may be rotatably fixed to the housing 421 and an opposite end of the shaft 422 may be connected to the holder 410.

The pins 423 are connected to the shaft 422. In more detail, the pins 423 extend outward from the shaft 422 in such a manner that the pins 423 are inclined with respect to a rotating axis of the shaft 422. In more detail, the pins 423 may vertically cross the rotating axis of the shaft 422.

The shaft 422 and the pins 423 may represent a high heat resistance property. For example, the shaft 422 and the pins 423 may be formed by using graphite or silicon carbon.

The compressed gas supply line 431 is connected to the housing 421. In more detail, the compressed gas supply line 431 is connected to the first flow passage 425. The compressed gas supply line 431 supplies compressed gas into the housing 421. In more detail, the compressed gas supply line 431 supplies the compressed gas into the receiving groove 423 through the first flow passage.

The compressed gas discharge line 432 is connected to the housing 421. In more detail, the compressed gas discharge line 432 is connected to the second flow passage 426. The compressed gas discharge line 432 may discharge the compressed gas supplied to the housing 421.

Gas having very low reactivity may be used as the compressed gas. The compressed gas may comprise inert gas such as argon.

The compressed gas introduced through the compressed gas supply line 431 and the first flow passage 425 is injected to the pins 423. Accordingly, the shaft 422 rotates and a rotating power of the shaft 422 is transferred to the holder 410 such that the wafer W is rotated.

Although it has been described that the holder 410 is rotated by the compressed gas, the embodiment is not limited thereto. The holder 410 may be rotated by, for example, a gear device.

In addition, although not shown in the drawings, the rotating driver 420 may further comprise a cover covering the receiving groove 423. The cover may be provided between the housing 421 and the holder 410. In this case, the shaft 422 may be connected to the holder 410 by passing through the cover.

The silicon carbide epitaxial layer growth apparatus according to the embodiment may further comprise a compressed gas generator for generating the compressed gas and supplying the generated compressed gas to the housing 421 through the compressed gas discharge line 432.

The holder 410 may be inclined with respect to the extension direction of the susceptor 200. Accordingly, the holder 410 may be inclined with respect to the upper susceptor 200 and the lower susceptor 200. That is, the wafer support member 400 may be inclined by an inclination support member 221 such that the holder 410 can be inclined with respect to the lower susceptor 200.

An angle θ between the holder 410 and the upper susceptor 200 may be in the range of about 5° to about 30° Accordingly, the wafer W may be inclined with respect to the extension direction of the susceptor 200.

The induction coil 600 is provided at an outer side of the chamber 100. In more detail, the induction coil 600 may surround an outer peripheral surface of the chamber 100. The induction coil 600 may inductively heat the susceptor 200 through electro-magnetic induction. The induction coil 600 may be wound around the outer peripheral surface of the chamber 100.

The susceptor 200 may be heated at a temperature ranging from about 1400° C. to 1600° C. by the induction coil 600. Source gas introduced into the susceptor 200 is decomposed into radical and the radical is injected to the wafer W by the injecting member 320. A silicon carbide epitaxial layer is formed on the wafer W by the radical injected to the wafer W.

As described above, the silicon carbide epitaxial growth apparatus according to the embodiment forms a thin film such as the epitaxial layer on a substrate such as the wafer W. That is, the silicon carbide epitaxial growth apparatus according to the embodiment may comprise a deposition apparatus.

As described above, the silicon carbide epitaxial growth apparatus according to the embodiment rotates the holder 410 using the rotating driver 420. Accordingly, the disposition apparatus according to the embodiment may form an epitaxial layer on the wafer W while rotating the wafer W.

Accordingly, the disposition apparatus according to the embodiment may form the epitaxial layer with a uniform thickness on the wafer W. That is, the disposition apparatus according to the embodiment may prevent an epitaxial layer from being thickly formed on the wafer W at a region in front of the susceptor 200.

FIG. 7 is an exploded perspective view showing a wafer support part according to a second embodiment. FIG. 8 is a side view showing a wafer support part according to a second embodiment. The previous embodiment will be incorporated herein by reference.

Referring to FIGS. 7 and 8, the disposition apparatus according to the embodiment comprises a fixing frame 600 and a plurality of wafer support members 401 and 402.

The fixing frame 600 is provided in the susceptor 200. The fixing frame 600 fixes the wafer support members 401 and 402. The fixing frame 600 may be formed by using graphite, or silicon carbide.

The wafer support members 401 and 402 may comprise a first wafer support member 401 and a second wafer support member 402.

The first wafer support part 402 may be fixed to the fixing frame 600 by a first connector 610. The first connector 610 may be connected to the fixing frame 600 and a housing of the first wafer support part 401.

The second wafer support member 402 is provided under the first wafer support member 401. The second wafer support member 402 may be fixed to the fixing frame 600 by a second connector 620. That is, the second connector 620 may be connected to the fixing frame 600 and a housing of the second wafer support member 402.

Different from the drawings, three or more wafer support parts may be provided. For example, a third wafer support member may be further provided under the second wafer support member 402.

Because the silicon carbide epitaxial layer growth apparatus according to the present embodiment comprises a plurality of wafer support parts 401 and 402, silicon carbide epitaxial layers may be simultaneously formed on a plurality of wafers W, respectively.

Therefore, the silicon carbide epitaxial layer growth apparatus according to the present embodiment may efficiently form an epitaxial layer with a uniform thickness.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A deposition apparatus comprising:
a susceptor into which reaction gas is introduced;
a holder supporting a substrate in the susceptor; and
a rotating driver for rotating the holder.

2. The deposition apparatus of claim 1, wherein the rotating driver comprises:
a shaft connected to the holder; and
a plurality of pins extending from the shaft while crossing a rotating axis of the shaft, and
wherein the shaft is rotated by compressed gas introduced through the pins.

3. The deposition apparatus of claim 2, wherein the pins vertically cross the rotating axis of the shaft.

4. The deposition apparatus of claim 2, wherein the pins are spaced apart from each other.

5. The deposition apparatus of claim 2, wherein the rotating driver comprises a housing receiving the shaft and the pins therein, and the housing is fixed to the susceptor.

6. The deposition apparatus of claim 5, further comprising a compressed gas supply line connected to the housing to supply the compressed gas to the pins.

7. The deposition apparatus of claim 6, further comprising a compressed gas discharge line connected to the housing to discharge the compressed gas.

8. The deposition apparatus of claim 2, wherein the compressed gas comprises inert gas.

9. The deposition apparatus of claim 1, wherein the holder is rotated at a speed ranging from 80 rpm to 120 rpm.

10. The deposition apparatus of claim 1, wherein the susceptor extends in one direction, and the holder is inclined to the extension direction of the susceptor.

11. The deposition apparatus of claim 1, wherein the shaft and the pins comprise graphite or silicon carbide.

12. A deposition apparatus comprising:
a susceptor into which reaction gas is introduced;
a first holder supporting a first substrate in the susceptor;
a first rotating driver for rotating the first holder;
a second holder supporting a second substrate on the first holder; and
a second rotating driver for rotating the second holder.

13. The deposition apparatus of claim 12, further comprising:
a third holder supporting a third substrate on the second holder; and
a third rotating driver for rotating the third holder.

14. The deposition apparatus of claim 12, further comprising a compressed gas supply part for supplying compressed gas to the first rotating driver and the second rotating driver,
wherein the first rotating driver and the second rotating driver are driven by the compressed gas.

15. The deposition apparatus of claim 14, further comprising a compressed gas discharge part for discharging the compressed gas.
